(19) United States
(12) Patent Application Publication
(10) Pub. No.: US 2005/0048680 A1
(43) Pub. Date: Mar. 3, 2005

(54) Printing one or more electrically conductive bonding lines to provide electrical conductivity in a circuit

(75) Inventor: Akira Matsunami, Beppu City (JP)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/651,787

(22) Filed: Aug. 29, 2003

(51) Int. Cl. H01L 21/00

(52) U.S. Cl. 438/21

(57) ABSTRACT

In one embodiment, a method for forming a circuit comprises generating bonding data specifying locations for one or more electrically conductive bonding lines and generating one or more printing instructions based on the bonding data. The method further comprises, using the printing instructions, printing the one or more electrically conductive bonding lines substantially on a surface of a substrate, the one or more electrically conductive bonding lines operable to provide electrical conductivity between a first element of the circuit and one or more second elements of the circuit.

### TECHNICAL FIELD OF THE INVENTION

This invention relates generally to circuits and more particularly to printing one or more electrically conductive bonding lines to provide electrical conductivity in a circuit.

### BACKGROUND

Integrated circuit packages and other structures such as printed circuit boards generally comprise one or more wire bonds between one or more elements of the structure. For example, an integrated circuit package may comprise one or more gold or other wire bonds that each connect a die associated with the integrated circuit package to one or more leads of the integrated circuit package. Using wire bonds to connect elements of integrated circuit packages or other structures may result in one or more problems. For example, there may be a danger of wire sagging or wire shortage as the number of wires increases or the distance between elements connected by wires increases. As another example, because the time required to bond the wires to the elements of the package or other structure may depend on the number of wires used, bonding the wires to elements of integrated circuit packages and other structures may be a relatively slow process, possibly increasing production time.

### SUMMARY OF THE INVENTION

According to the present invention, certain disadvantages and problems associated with previous techniques for providing electrical conductivity in a circuit may be reduced or eliminated.

In one embodiment, a method for forming a circuit comprises generating bonding data specifying locations for one or more electrically conductive bonding lines and generating one or more printing instructions based on the bonding data. The method further comprises, using the printing instructions, printing the one or more electrically conductive bonding lines substantially on a surface of a substrate, the one or more electrically conductive bonding lines operable to provide electrical conductivity between a first element of the circuit and one or more second elements of the circuit.

In another embodiment, a printed circuit board comprises a first element coupled to a surface of the printed circuit board and a second element coupled to the surface of the printed circuit board. The printed circuit board further comprises one or more electrically conductive bonding lines printed on the surface of the printed circuit board to provide electrical conductivity between the first element and the second element.

In another embodiment, a method for forming a circuit comprises positioning a first element having a first surface and positioning a second element having a second surface such that a void exists between the first surface and the second surface. The method further comprises substantially filling the void with a material such that a third surface is formed between the first surface and the second surface, the first surface, the second surface, and the third surface forming a bonding surface. The method further comprises printing one or more electrically conductive bonding lines on at least a portion of the bonding surface, the one or more electrically conductive bonding lines operable to provide electrical conductivity between the first element and the second element.

Particular embodiments of the present invention may provide one or more technical advantages. In certain embodiments, using the one or more printed electrically conductive bonding lines may allow finer pitch (i.e. center-to-center separation) of bonding lines in an integrated circuit package or other structure relative to using one or more bonding wires. In certain embodiments, problems associated with sagging wire bonds or wire shortages may be reduced or eliminated. For example, in certain embodiments improvements in the quality of connections may occur due to relatively accurate printing technology instead of mechanical wire bonds. In certain embodiments, the time required to produce integrated circuit packages or other structures may be decreased because the time to print the one or more electrically conductive bonding lines may not depend on the number of bonding lines to be printed (as opposed to dependency on the number of wires in previous methods). In certain embodiments, a printer used to print the electrically conductive bonding lines may provide desirable resolution, detail, ultra-fine sizes, and accuracy.

Certain embodiments of the present invention may provide some, all, or none of the above technical advantages. Certain embodiments may provide one or more other technical advantages, one or more of which may be readily apparent to those skilled in the art from the figures, descriptions, and claims included herein.

### BRIEF DESCRIPTION OF THE DRAWINGS

For a more complete understanding of the present invention and features and advantages thereof, reference is now made to the following description, taken in conjunction with the accompanying drawings, in which:

FIG. 1 illustrates an example system for forming a circuit using one or more electrically conductive bonding lines printed on a substrate;

FIG. 2 illustrates an example substrate sheet on which one or more electrically conductive bonding lines may be printed to form one or more circuits according to the present invention;

FIGS. 3A-3E illustrate an example method for forming an example circuit, which is an integrated circuit package, using one or more printed electrically conductive bonding lines;

FIG. 4 illustrates a cross-sectional view of an example integrated circuit package formed according to the present invention; and

FIGS. 5A-5D illustrate an example method for forming an integrated circuit package according to the present invention.

### DESCRIPTION OF EXAMPLE EMBODIMENTS

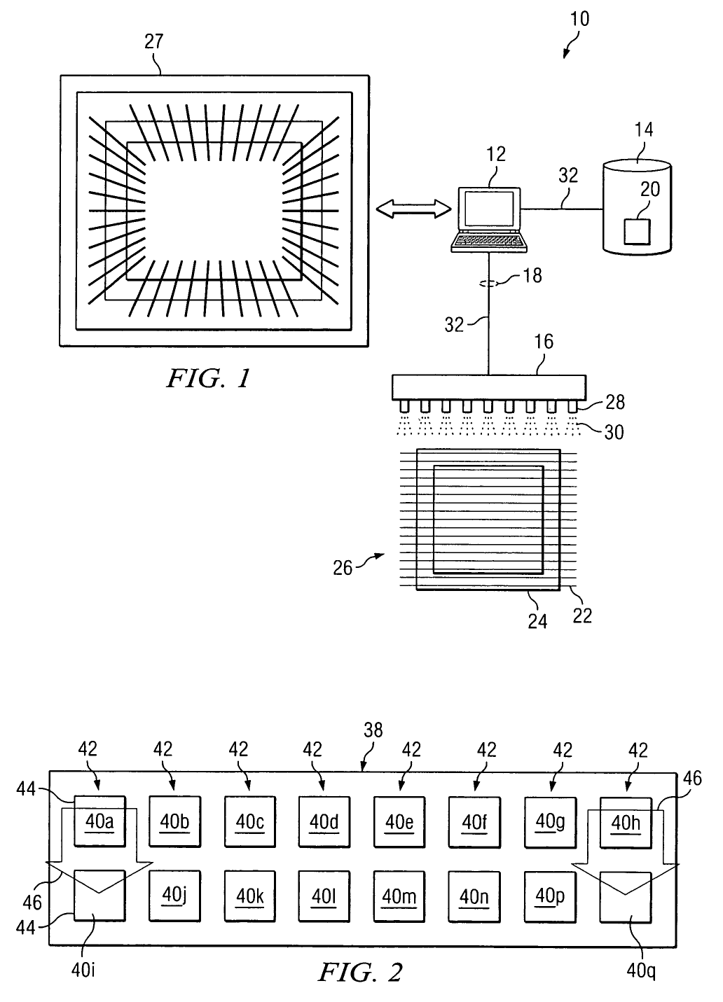

FIG. 1 illustrates an example system 10 for forming a circuit using one or more electrically conductive bonding lines printed on a substrate. System 10 may comprise a computer system 12, a memory 14, and a printer 16. In general, computer system 12 is operable to generate one or more printing instructions 18 based on bonding data 20 stored in memory 14, and printer 16 is operable to print one or more electrically conductive bonding lines 22 substantially on the surface of a substrate 24 based on printing instructions 18. Electrically conductive bonding lines 22 are operable to provide electrical conductivity between a first element of a circuit 26 and one or more second elements of circuit 26. In one embodiment, electrically conductive bonding lines 22 are used in lieu of standard gold wire bonding.

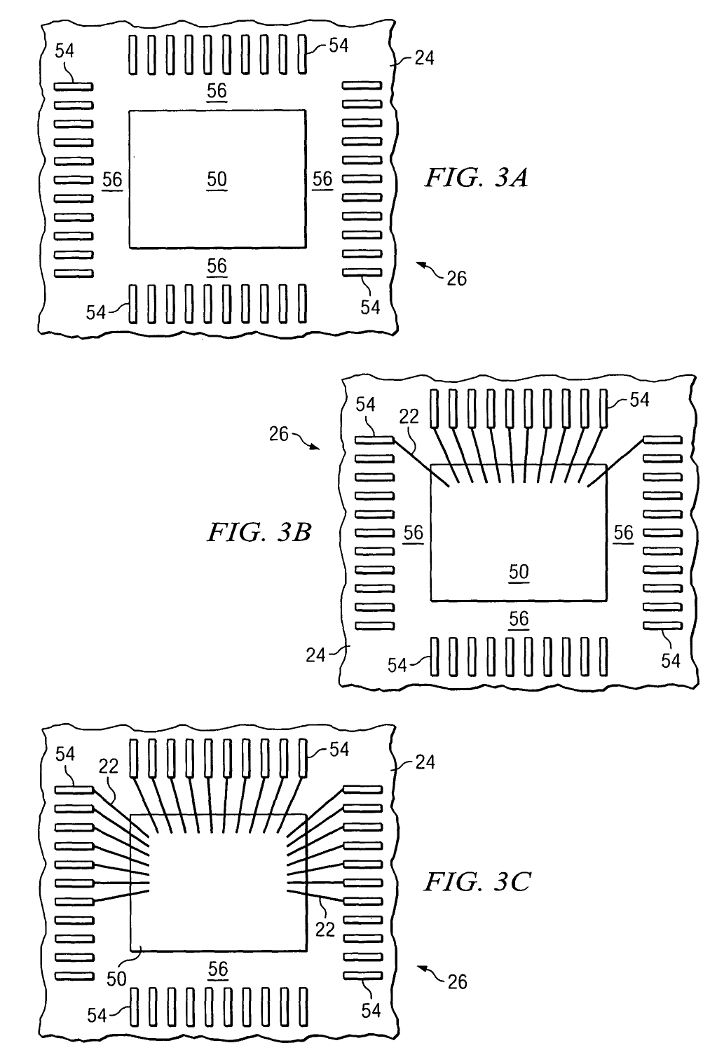

Circuit 26 may include an integrated circuit package such as a ball grid array (BGA) type circuit, a leaded package, a printed circuit board package, or any other suitable circuit, according to particular needs. Although one circuit 26 is shown, the present invention contemplates system 10 forming multiple circuits using one or more electrically conductive bonding lines 22 printed on a substrate 24. For example, as described in more detail below with reference to FIG. 2, substrate 24 may comprise a substrate or lead frame sheet that comprises multiple circuit formation areas. In one embodiment, substrate 24 comprises a die pad, a dielectric portion, leads such as inner or outer leads, or any other suitable components. However, the present invention contemplates substrate 24 including any suitable material and components according to particular needs.

Memory 14 may be operable to store bonding data 20 specifying locations for one or more electrically conductive bonding lines 22 for a particular circuit 26. Bonding data 20 may comprise a location of a first element, locations of one or more second elements, a path to traverse from one element to another element, a type identity of the bonding lines 22 to be printed, a thickness for the bonding lines 22 to be printed, or any other suitable information for specifying locations for one or more electrically conductive bonding lines 22 for a particular circuit 26. In one embodiment, bonding data 20 is generated by performing one or more simulations 27 to determine locations for electrically conductive bonding lines 22. For example, computer system 12 may perform one or more simulations 27 to determine locations for electrically conductive bonding lines 22. Simulations 27 may be performed for determining bonding data 20 for one or more circuits 26. Simulations 27 may be performed using Computer Aided Drafting (CAD) software, for example; however, the present invention contemplates generating bonding data 20 in any suitable manner.

Computer system 12 may comprise one or more processors that are collectively operable to generate one or more printing instructions 18 based on bonding data 20. In one embodiment, printing instructions 18 are generated by converting bonding data 20 into one or more computerized instructions that configure printer 16 to print electrically conductive bonding lines 22 according to bonding data 20. For example, computer system 12 may convert bonding data 20 into printing instructions 18 using one or more device drivers. In one embodiment, a picture file such as a JPEG or JIF file, for example, may be created from bonding data 20 (e.g., using CAD software), and the picture file may be scanned and printed according to standard or other methods.

Computer system 12 and memory 14 may comprise one or more computers at one or more locations and may share data storage, communications, or other resources according to particular needs. For example, functionality described in connection with computer system 12 and memory 14 may be provided using a single computer system, which in a particular embodiment might comprise a conventional desktop or laptop computer connected to a printer 16. Computer system 12 may comprise one or more suitable input devices, output devices, mass storage media, processors, memory, or other components for receiving, processing, storing, and communicating information according to the operation of system 10. Memory 14 may comprise any memory or database module and may take the form of volatile or non-volatile memory including, without limitation, magnetic media, optical media, random access memory (RAM), read-only memory (ROM), removable media, or any other suitable local or remote memory component.

Printer 16 may be or may comprise functionality similar to a bubble jet printer, an ink jet printer, a laser printer, or any other suitable type of printer according to particular needs. Printer 16 may comprise one or more nozzles 28 operable to discharge electrically conductive material 30 for printing bonding lines 22. Nozzles 28 may have any suitable pitch (i.e., center-to-center separation between nozzles 28) according to particular needs. In one embodiment, nozzles 28 have a pitch of 40 μm. Electrically conductive material 30 may comprise electrically conductive ink or any other suitable material according to particular needs. For example, electrically conductive material 30 may comprise gold, silver, copper, or any other suitable metal or metal alloy. In one embodiment, electrically conductive material 30 is adhesive. For example, it may be desirable for electrically conductive material 30 to be adhesive so that it bonds to the surface of substrate 24.

Electrically conductive bonding lines 22 printed by printer 16 using electrically conductive material 30 may have any suitable width according to particular needs. In one embodiment, electrically conductive bonding lines 22 may have a width of 24.3 μm. In certain embodiments, the width of electrically conductive bonding lines 22 may be smaller than the width of traditional wire bonds, which may allow smaller circuits to be constructed.

Printer 16 may be operable to print electrically conductive bonding lines 22 substantially on a surface of substrate 24. For example, printer 16 may use printing instructions 18 to print bonding lines 22. The one or more bonding lines 22 provide electrical conductivity between a first element of circuit 26 and one or more second elements of circuit 26. In one embodiment, the first element and the one or more second elements each comprise components of an integrated circuit package. For example, the first element may comprise a die and the one or more second elements may each comprise leads, such as inner leads, of the integrated circuit package. In another embodiment, the first element comprises a first integrated circuit associated with a printed circuit board and the one or more second elements each comprise a second integrated circuit associated with the printed circuit board.

Computer system 12 and memory 14 may be associated with a single computer or a network according to particular needs. Printer 16 may comprise a stand-alone printer, a network printer, or any other suitable type of printer 16 according to particular needs. Computer system 12, memory 14, and printer 16 may be coupled using one or more links 32. Links 32 may comprise direct connections, one or more local area networks (LANs), metropolitan area networks (MANs), wide area networks (WANs), a global computer network such as the Internet, or any other wireline, optical, wireless, or other links.

FIG. 2 illustrates an example substrate sheet 38 on which one or more electrically conductive bonding lines 22 may be printed to form one or more circuits 26 according to the present invention. Substrate sheet 38 may comprise one or more circuit substrates 40, each of which may eventually form at least a portion of a circuit 26. In one embodiment, each circuit substrate 40 may comprise a die pad, a dielectric portion, leads such as inner or outer leads, or any other suitable components. However, the present invention contemplates each circuit substrate 40 including any suitable material and components according to particular needs. Although substrate sheet 38 is described as a substrate sheet, the present invention contemplates substrate sheet 38 being a lead frame sheet 38, or any other suitable type of sheet on which one or more circuits 26 may be formed. In one embodiment, substrate sheet 38 is a printed circuit board and circuit substrates 40 comprise areas on which one or more integrated circuits may be attached.

Circuit substrates 40 may be arranged in one or more columns 42 and one or more rows 44. Although a particular number of columns 42 and rows 44 are illustrated, the present invention contemplates substrate sheet 38 including any suitable number of columns 42 and rows 44 according to particular needs. Additionally, although a particular number of circuit substrates 40 are illustrated in each column 42 and each row 44, the present invention contemplates each column 42 and each row 44 including any suitable number of circuit substrates 40 according to particular needs. Furthermore, although the illustrated substrate sheet 38 is shown as a substantially perfect grid, the present invention contemplates any suitable arrangement of circuit substrates 40 on substrate sheet 38. Substrate sheet 38 may be fed into or otherwise processed by printer 16 for printing one or more electrically conductive bonding lines 22 on substrate sheet 38. For example, substrate sheet 38 may be fed into printer 16 in direction 46.

In one embodiment, a circuit 26 formed using system 10 comprises one of a plurality of circuits 26 to be formed on a substrate sheet 38 and arranged in one or more rows 44 and one or more columns 42. Bonding data 20 may comprise sheet bonding data 20 that specifies locations for one or more electrically conductive bonding lines 22 for each circuit 26 to be formed on substrate sheet 38, on circuit substrates 40 for example. As an example, first sheet bonding data 20 may specify bonding data 20 for a circuit 26 to be formed on circuit substrate 40a, second sheet bonding data 20 may specify bonding data 20 for a circuit 26 to be formed on circuit substrate 40b, and so on. In one embodiment, sheet bonding data 20 includes bonding data 20 for at least one circuit 26 that is different from bonding data 20 for at least one other circuit 26.

Printing instructions 18 may comprise sheet printing instructions 18 that are based on sheet bonding data 20. As an example, first sheet printing instructions 18 may specify printing instructions 18 for a circuit 26 to be formed on circuit substrate 40a, second sheet printing instructions 18 may specify printing instructions 18 for a circuit 26 to be formed on circuit substrate 40b, and so on. In one embodiment, sheet printing instructions 18 comprises printing instructions 18 for at least one circuit 26 that is different from printing instructions 18 for at least one other circuit 26. Printer 16 may be operable to print the one or more electrically conductive lines 22 by repeating the following steps until a desired number of circuits 26 are formed on substrate sheet 38. Printer 16 may align one or more nozzles 28 of printer 16 according to sheet printing instructions 18. Different nozzles 28 may be aligned differently based on different sheet printing instructions 18. Printer 16 may discharge electrically conductive material 30 from nozzles 28, electrically conductive material 30 forming electrically conductive lines 22 for each circuit 26 in a row 44 (i.e., at each circuit substrate 40). Printer 16 may then advance substrate sheet 38 to a next row 44 of circuits 26 (i.e., circuit substrates 40). For example, printer 16 may advance substrate sheet 38 in direction 46.

Prior methods for connecting elements of circuits using, for example, gold bond wiring, generally required each circuit substrate 40 in a column 42 to be bonded individually before moving to the next column 42. For example, in the illustrated embodiment, wire bonding according to prior methods may require bonding circuit substrates 40 in the following order: 40a, 40i, 40b, 40j, 40c, 40k, and so on. As a result, the bonding time for one substrate sheet 38 may depend on one or more of the following factors: the bonding time per substrate sheet 38; one wire bonding time; the number of wires per circuit substrate 40; the number of circuit substrates 40 per substrate sheet 38; or any other suitable factors.

In certain embodiments of the present invention, however, multiple circuit substrates 40 in an entire row 44 may be bonded at the same time, if desirable. For example, according to one embodiment it is possible to print one or more electrically conductive bonding lines 22 on circuit substrates 40a, 40b, 40c, 40d, 40e, 40f, 40g, and 40h substantially simultaneously. Substantially simultaneously may comprise printing electrically conductive bonding lines 22 for each circuit substrates 40 in a particular row 44 exactly simultaneously or sequentially from left to right or from right to left, with the time varying according to particular speeds of printers 16. As a result, the bonding time for substrate sheet 38 may depend on one or more of the following factors: the bonding time per substrate sheet 38; the printer speed to move the width of substrate sheet 38; the number of circuit substrates 40 per substrate sheet 38; or any other suitable factors. Thus, the bonding time per substrate sheet 38 may be reduced because the time to print electrically conductive bonding line 22 using printer 16 may, in certain embodiments, be less than the time needed to attach each wire per circuit substrate 40 as with previous methods.

Particular embodiments of the present invention may provide one or more technical advantages. In certain embodiments, using the one or more printed electrically conductive bonding lines 22 may allow finer pitch (i.e. center-to-center separation) of bonding lines 22 in an integrated circuit package or other structure relative to using one or more bonding wires. In certain embodiments, problems associated with sagging wire bonds or wire shortages may be reduced or eliminated. For example, in certain embodiments, improvements in the quality of connections may occur due to relatively accurate printing technology instead of mechanical wire bonds. In certain embodiments, the time required to produce integrated circuit packages or other structures may be decreased because the time to print the one or more electrically conductive bonding lines 22 may be less than the time to attach wires as in previous methods. In certain embodiments, using printer 16 to print electrically conductive bonding lines 22 may provide desirable resolution, detail, ultra-fine sizes, and accuracy.

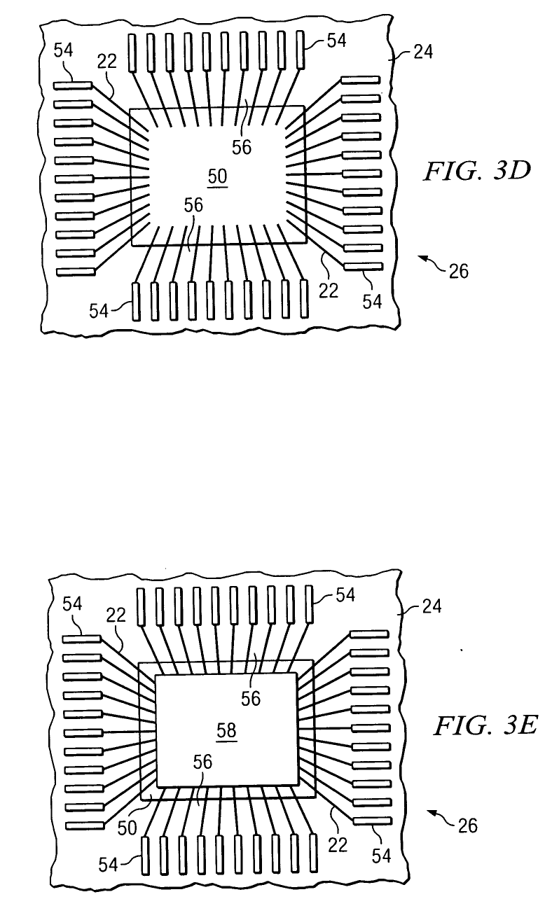

FIGS. 3A-3E illustrate an example method for forming an example circuit 26, which is an integrated circuit package 26, using one or more printed electrically conductive bonding lines 22. For example, integrated circuit package 26 may comprise a ball grid array (BGA)-type integrated circuit package. As discussed above, integrated circuit package 26 may be formed alone or may be one of a plurality of integrated circuit packages 26 formed on a substrate sheet 38. As illustrated in FIG. 3A, substrate 24 is provided. Substrate 24 may comprise a die pad 50 and one or more second elements 54 that are formed on or within substrate 24. In one embodiment, die pad 50 comprises circuitry surrounded by, for example, a dielectric or other suitable material 56. In one embodiment, die pad 50 may comprise a standard laminate. In certain embodiments, die pad 50 may form a portion of a substrate of integrated circuit package 26 for coupling integrated circuit package 26 to one or more printed circuit boards, in a BGA assembly for example. Die pad 50 may have any suitable area and shape, according to particular needs. Although die pad 50 is described as a die pad, the present invention contemplates die pad 50 being any suitable component according to particular needs. In one embodiment, second elements 54 comprise leads 54, such as inner leads, of substrate 24. For example, leads 54 may comprise metal traces formed on or within substrate 24.

As illustrated in FIGS. 3B through 3D, electrically conductive bonding lines 22 may be printed on substrate 24 and couple one or more of second elements 54 to die pad 50. Each electrically conductive bonding line 22 may contact any suitable portion of its corresponding second element 54 and die pad 50 according to particular needs. Electrically conductive bonding lines 22 may be printed by printer 16 substantially on a surface of substrate 24. For example, printer 16 may use printing instructions 18 to print bonding lines 22. In one embodiment, electrically conductive bonding lines 22 are used in lieu of standard gold wire bonding.

As illustrated in FIG. 3E, a first element 58 may be coupled to die pad 50. In one embodiment, first element 58 comprises a die. Electrically conductive bonding lines 22 printed on substrate 24 are therefore operable to provide electrical conductivity between first element 58 and second elements 54.

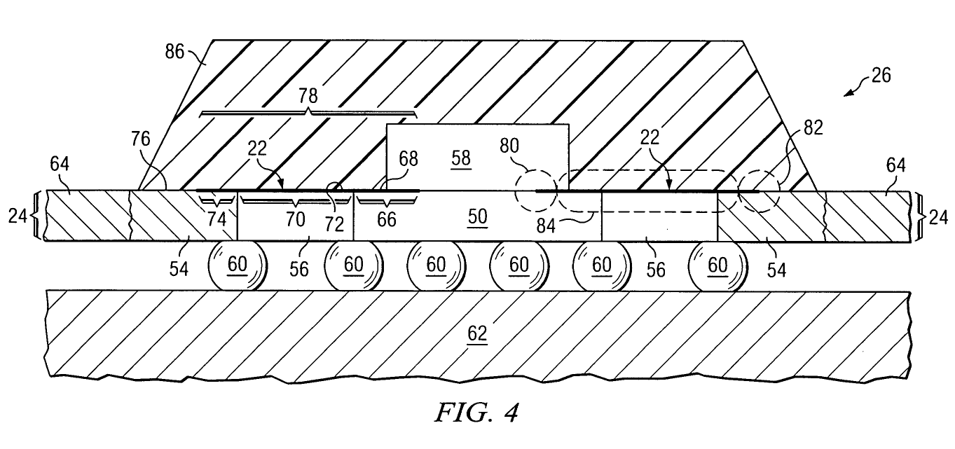

FIG. 4 illustrates a cross-sectional view of an example integrated circuit package 26 formed according to the present invention. For example, integrated circuit package 26 may be formed according to the method described above with reference to FIGS. 3A-3E. Although a particular embodiment is illustrated in FIG. 4, the present invention is not intended to be so limited and the illustrated integrated circuit package 26 is for example purposes only.

Integrated circuit package 26 comprises multiple conductive balls (e.g., solder balls) 60 coupling a substrate 24 to a printed circuit board 62. Substrate 24 comprises die pad 50, dielectric material 56, inner leads 54, and outer leads 64. Integrated circuit package 26 also comprises die 58 coupled to die pad 50. At least a portion 66 of a surface 68 of die pad 50, at least a portion 70 of a surface 72 of dielectric material 56, and at least a portion 74 of a surface 76 of inner leads 54 may form a bonding surface 78 of substrate 24. Integrated circuit package 26 comprises electrically conductive bonding lines 22 that provide electrical conductivity between die 58 and inner leads 54. In one embodiment, each electrically conductive bonding line 22 comprises a first end 80, a second end 82, and a body portion 84 between first end 80 and second end 82. First end 80, second end 82, and substantially all of body portion 84 may be printed on the surface of substrate 24, on bonding surface 78 for example. Although certain reference numerals are drawn on only one side of FIG. 4, this is for clarity only. The present invention contemplates, in certain embodiments, the bonding lines 22 on both sides of integrated package 26 having substantially similar features. The present invention contemplates electrically conductive bonding lines 22 being printed on any suitable portions of inner leads, dielectric portions, and die pad. Although the illustrated integrated circuit package 26 is two-dimensional, the present invention contemplates integrated circuit package 26 being three-dimensional and extending into and out of the page. As such, it is not required that electrically conductive bonding lines 22 be printed on the entire surface of substrate 24 throughout this third dimension.

In a particular embodiment, die 58 is attached to die pad 50 subsequent to printer 16 printing the one or more electrically conductive bonding lines 22. Bonding surface 78 of substrate 24 may be substantially planar, contoured, or otherwise formed and may include sharp changes in elevation in certain embodiments. It may be desirable for bonding surface 78 of substrate 24 to be formed such that an electrically conductive bonding line 22 printed on bonding surface 78 is sufficiently continuous to provide conductivity between first element 58 (e.g., die 58) and second element 54 (e.g., inner leads 54). Integrated circuit package 26 may also comprise a mold compound package body 86 or other suitable package body 86 substantially covering one or more components of integrated circuit package 26.

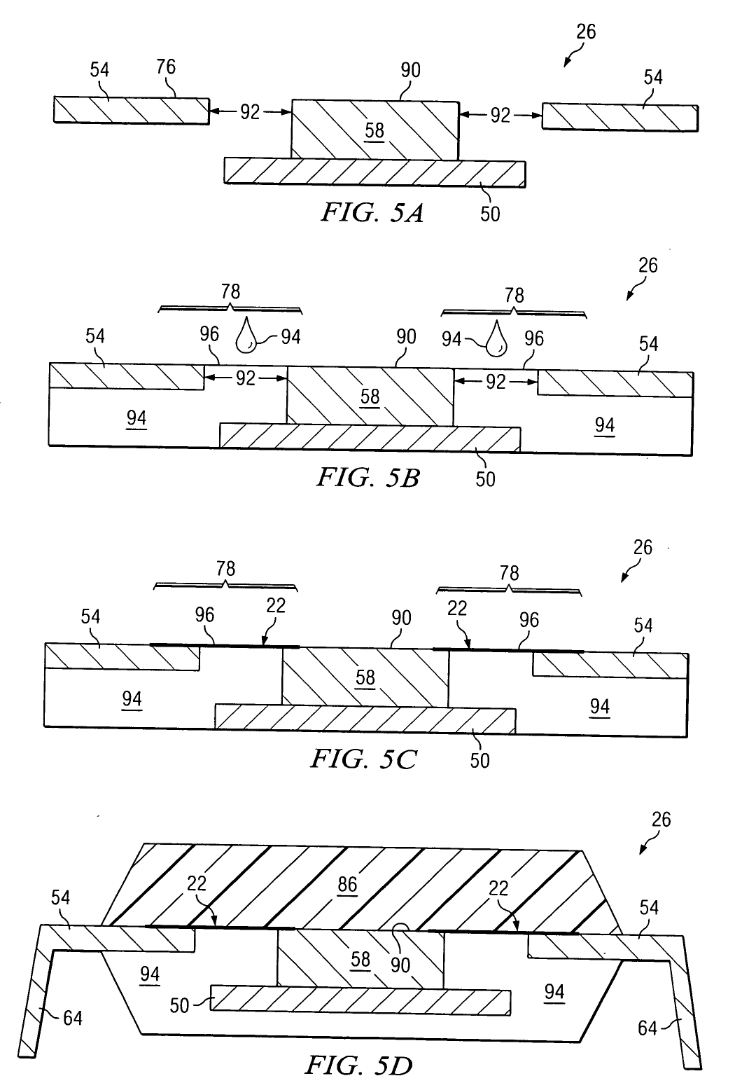

FIGS. 5A-5D illustrate an example method for forming an integrated circuit package 26 according to the present invention. As discussed above, integrated circuit package 26 may be formed alone or may be one of a plurality of integrated circuit packages 26 formed on a substrate sheet 38. In particular, integrated circuit package 26 may be formed as one of a plurality of packages formed on a frame sheet 38. As illustrated in FIG. 5A, a first element 58 may be positioned on a die pad 50, first element including a first surface 90. In one embodiment, first element 58 comprises a die 58. Die pad 50 may be formed within or substantially on a surface of a lead frame substrate (not shown). One or more second elements 54 each having a second surface 76 may be positioned such that one or more voids 92 exist between first surface 90 and second surface 76. In one embodiment, second elements 54 may comprise a lead such as an inner lead of integrated circuit package 26.

As shown in FIG. 5B, voids 92 may be substantially filled with a material 94 such that third surfaces 96 are formed between first surface 90 and second surfaces 76. Material 94 may comprise a resin such as a clear resin or any other material suitable for filling voids 92 according to particular needs. In one embodiment, it is desirable for material 94 to comprise a non-conductive material. At least portions of first surface 90, second surfaces 76, and third surfaces 96 may form one or more bonding surfaces 78. Bonding surfaces 78 may be substantially planar, contoured, or otherwise formed and may include sharp changes in elevation in certain embodiments. It may be desirable for each bonding surface 78 to be formed such that an electrically conductive bonding line 22 printed on bonding surface 78 is sufficiently continuous to provide electrical conductivity between first element 58 and a second element 54.

As illustrated in FIG. 5C, electrically conductive bonding lines 22 may be printed on bonding surfaces 78 and couple one or more second elements 54 to first element 58. Each electrically conductive bonding line 22 may contact any suitable portion of its corresponding second element 54 and first element 58 according to particular needs. As described above, electrically conductive bonding lines 22 may be printed by printer 16 according to one or more printing instructions 18, which may be generated by computer system 12 based on bonding data 20 stored in memory 14. Electrically conductive lines 22 printed on substrate 24 (i.e., bonding surface 78) are operable to provide electrical conductivity between first element 58 and second elements 54.

As shown in FIG. 5D, a mold compound package body 86 or other suitable package body 86 may be coupled to integrated circuit package 26. In certain embodiments, one or more outer leads 64 may be coupled to integrated circuit package 26, for example to second elements 54.

Although the present invention has been described with several embodiments, diverse changes, substitutions, variations, alterations, and modifications may be suggested to one skilled in the art, and it is intended that the invention encompass all such changes, substitutions, variations, alterations, and modifications as fall within the spirit and scope of the appended claims.

1. A method for forming a circuit, comprising:
generating bonding data specifying locations for one or more electrically conductive bonding lines;
generating one or more printing instructions based on the bonding data;
using the printing instructions, printing the one or more electrically conductive bonding lines substantially on a surface of a substrate, the one or more electrically conductive bonding lines operable to provide electrical conductivity between a first element of the circuit and one or more second elements of the circuit.

2. The method of claim 1, wherein the one or more electrically conductive bonding lines comprise conductive ink.

3. The method of claim 1, wherein generating the one or more printing instructions comprises converting the bonding data into one or more instructions that configure the printer to print the one or more electrically conductive bonding lines.

4. The method of claim 1, wherein the first element and the one or more second elements each comprise components of an integrated circuit package.

5. The method of claim 1, wherein:
the first element comprises a first integrated circuit associated with a printed circuit board; and
the one or more second elements each comprise a second integrated circuit associated with the printed circuit board.

6. The method of claim 1, wherein the first element comprises a die of an integrated circuit package and the one or more second elements comprise leads of the integrated circuit package.

7. The method of claim 6, further comprising attaching the die to a die pad coupled to the top surface of the substrate, the die being attached to the die pad subsequent to printing the one or more electrically conductive bonding lines.

8. The method of claim 1, wherein:
the circuit comprises one of a plurality of circuits to be formed on a substrate sheet and arranged in one or more rows and one or more columns;
the bonding data comprises sheet bonding data that specifies locations for one or more electrically conductive bonding lines for at least one circuit to be formed on the substrate sheet;
the printing instructions comprise sheet printing instructions that are based on the sheet bonding data; and
printing the one or more electrically conductive lines comprises repeating the following steps until a desired number of circuits are formed on the substrate sheet:
aligning one or more nozzles of a printer according to the sheet printing instructions;
discharging electrically conductive material from the nozzles, the electrically conductive material forming the one or more electrically conductive lines for each circuit in a row; and
advancing the sheet to a next row of circuits.

9. The method of claim 8, wherein the sheet printing instructions comprise:
first sheet printing instructions for a first circuit of the substrate sheet;
second sheet printing instructions for a second circuit of the substrate sheet;
the second sheet printing instructions are different from the first sheet printing instructions.

10. An integrated circuit package, comprising:
a substrate layer comprising:
a substrate material having a surface;
a die pad having a surface;
one or more leads, each lead having a surface, the surface of the die pad, the surface of each lead, and the surface of the substrate material forming a bonding surface of the substrate layer; and
one or more electrically conductive bonding lines printed on the bonding surface of the substrate layer to provide electrical conductivity between a die coupled to the die pad and the one or more leads.

11. The package of claim 10, wherein the one or more electrically conductive bonding lines are printed by:
generating bonding data specifying locations for the one or more electrically conductive bonding lines;
generating one or more printing instructions based on the bonding data;
using the printing instructions, printing the one or more electrically conductive bonding lines on the bonding surface of the substrate layer.

12. The package of claim 11, wherein the bonding data was generated by performing one or more simulations to determine locations for the one or more electrically conductive bonding lines.

13. The package of claim 11, wherein the one or more printing instructions were generated by converting the bonding data into one or more instructions that configured the printer to print the one or more electrically conductive bonding lines.

14. The package of claim 10, wherein the one or more electrically conductive bonding lines comprise conductive ink.

15. The package of claim 10, wherein:
each of the one or more electrically conductive lines comprises a first end, a second end, and a body portion between the first end and second end; and
the first end, the second end, and substantially all of the body portion being printed on the bonding surface of the substrate layer.

16. The package of claim 10, wherein the die was attached to the die pad subsequent to printing the one or more electrically conductive bonding lines.

17. The package of claim 10, further comprising a mold compound package body substantially covering the die, the one or more electrically conductive bonding lines; and a portion of the one or more leads.

18. The package of claim 10, wherein the bonding surface of the substrate layer is substantially planer.

19. The package of claim 10, wherein the bonding surface of the substrate layer comprises contours.

20. A printed circuit board, comprising:
a first element coupled to a surface of the printed circuit board;
a second element coupled to the surface of the printed circuit board; and
one or more electrically conductive bonding lines printed on the surface of the printed circuit board to provide electrical conductivity between the first element and the second element.
